(19) United States
(12) Patent Application Publication
(10) Pub. No.: US 2023/0268905 A1
(43) Pub. Date: Aug. 24, 2023

(54) RESONATOR DEVICE AND METHOD OF MANUFACTURING RESONATOR DEVICE

(71) Applicant: SEIKO EPSON CORPORATION, Tokyo (JP)

(72) Inventors: Masahiro Fujii, Shiojiri-shi (JP); Ryuichi Kurosawa, Suwa-gun (JP)

(21) Appl. No.: 18/172,651

(22) Filed: Feb. 22, 2023

(30) Foreign Application Priority Data
Feb. 24, 2022 (JP) 2022-026460

(51) Int. Cl. H03H 9/19; H03H 3/02

(52) U.S. Cl. CPC H03H 9/19; H03H 3/02

(57) ABSTRACT

A resonator device includes an element substrate including a frame part having a first surface and a second surface in a front-back relationship with each other, and a resonator element which is coupled to the frame part, and is arranged inside the frame part, a first substrate which is arranged at the first surface side, and has a third surface faced to the first surface, a first bonding layer which is arranged between the element substrate and the first substrate, and which is configured to bond the first surface and the third surface to each other, a second substrate which is arranged at the second surface side, and has a fourth surface faced to the second surface, a second bonding layer which is arranged between the element substrate and the second substrate, and which is configured to bond the second surface and the fourth surface to each other, a housing part which is surrounded by the frame part, the first substrate, and the second substrate, and which houses the resonator element, and a getter layer which is arranged on the fourth surface, exposed to the housing part, and has a gas adsorptive property.

The present application is based on, and claims priority from JP Application Serial Number 2022-026460, filed Feb. 24, 2022, the disclosure of which is hereby incorporated by reference herein in its entirety.

### BACKGROUND

### 1. Technical Field

The present disclosure relates to a resonator device and a method of manufacturing a resonator device.

### 2. Related Art

An electronic device described in JP-A-2020-88589 (Document 1) is provided with a quartz crystal vibrating plate, and a first sealing member and a second sealing member which vertically sandwich the quartz crystal vibrating plate to airtightly seal a vibrating part. Further, by diffusely bonding a bonding pattern provided to the quartz crystal vibrating plate and a bonding pattern provided to the first sealing member to each other, the quartz crystal vibrating plate and the first sealing member are bonded to each other, and by diffusely bonding the bonding pattern provided to the quartz crystal vibrating plate and a bonding pattern provided to the second sealing member to each other, the quartz crystal vibrating plate and the second sealing member are bonded to each other.

However, in the resonator device described in Document 1, there is a problem that a loss of vacuum occurs in a cavity due to an influence of a residual gas after the airtight sealing, and deterioration in vibration characteristics occurs due to a fluctuation in a vibrational frequency, a decrease in Q-value, and so on.

### SUMMARY

A resonator device according to the present disclosure includes an element substrate including a frame part having a first surface and a second surface in a front-back relationship with each other, and a resonator element which is coupled to the frame part, and is arranged inside the frame part, a first substrate which is arranged at the first surface side, and has a third surface faced to the first surface, a first bonding layer which is arranged between the element substrate and the first substrate, and which is configured to bond the first surface and the third surface to each other, a second substrate which is arranged at the second surface side, and has a fourth surface faced to the second surface, a second bonding layer which is arranged between the element substrate and the second substrate, and which is configured to bond the second surface and the fourth surface to each other, a housing part which is surrounded by the frame part, the first substrate, and the second substrate, and which is configured to house the resonator element, and a getter layer which is arranged on the fourth surface, exposed to the housing part, and has a gas adsorptive property.

A method of manufacturing a resonator device according to another aspect of the present disclosure includes an element substrate preparation step of preparing an element substrate including a frame part having a first surface and a second surface in a front-back relationship with each other, a resonator element which is coupled to the frame part, and is arranged inside the frame part, and a frame-part-side first bonding layer arranged on the first surface of the frame part, a first substrate preparation step of preparing a first substrate provided with a substrate-side first bonding layer arranged on a third surface, a first bonding step of bonding the frame-part-side first bonding layer and the substrate-side first bonding layer to each other to form a first bonding layer, and then bonding the frame part and the first substrate to each other via the first bonding layer, a second substrate preparation step of preparing a second substrate having a fourth surface on which a getter layer having a gas adsorptive property, and a substrate-side second bonding layer are arranged, a frame-part-side second bonding layer formation step of forming a frame-part-side second bonding layer on the second surface of the frame part, and a second bonding step of bonding the frame-part-side second bonding layer and the substrate-side second bonding layer to each other to form a second bonding layer, and then bonding the frame part and the second substrate to each other via the second bonding layer.

### BRIEF DESCRIPTION OF THE DRAWINGS

FIG. 1 is a cross-sectional view of a resonator device according to a first embodiment.

FIG. 2 is a plan view showing an element substrate provided to the resonator device.

FIG. 3 is a plan view of a first substrate provided to the resonator device.

FIG. 4 is a flowchart showing a manufacturing process of the resonator device.

FIG. 5 is a cross-sectional view showing a method of manufacturing the resonator device.

FIG. 6 is a cross-sectional view showing the method of manufacturing the resonator device.

FIG. 7 is a cross-sectional view showing the method of manufacturing the resonator device.

FIG. 8 is a cross-sectional view showing the method of manufacturing the resonator device.

FIG. 9 is a cross-sectional view showing the method of manufacturing the resonator device.

FIG. 10 is a cross-sectional view showing the method of manufacturing the resonator device.

FIG. 11 is a cross-sectional view showing the method of manufacturing the resonator device.

FIG. 12 is a cross-sectional view showing the method of manufacturing the resonator device.

FIG. 13 is a cross-sectional view showing the method of manufacturing the resonator device.

FIG. 14 is a cross-sectional view showing the method of manufacturing the resonator device.

FIG. 15 is a cross-sectional view showing the method of manufacturing the resonator device.

FIG. 16 is a cross-sectional view showing the method of manufacturing the resonator device.

FIG. 17 is a cross-sectional view showing the method of manufacturing the resonator device.

FIG. 18 is a cross-sectional view showing the method of manufacturing the resonator device.

FIG. 19 is a cross-sectional view of a resonator device according to a second embodiment.

FIG. 20 is a cross-sectional view of a resonator device according to a third embodiment.

### DESCRIPTION OF EXEMPLARY EMBODIMENTS

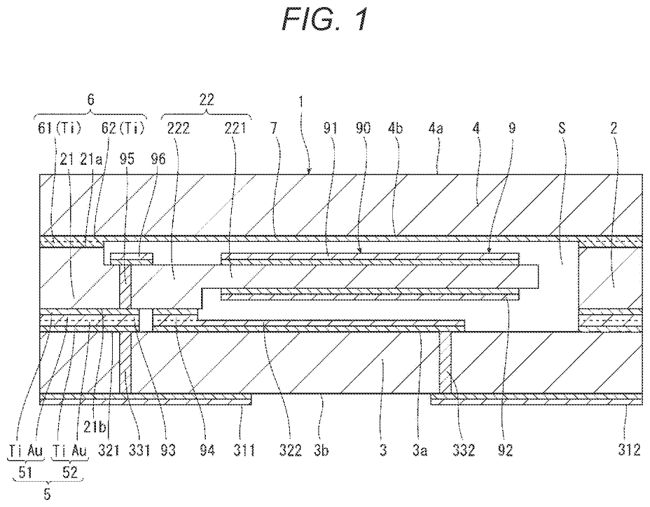

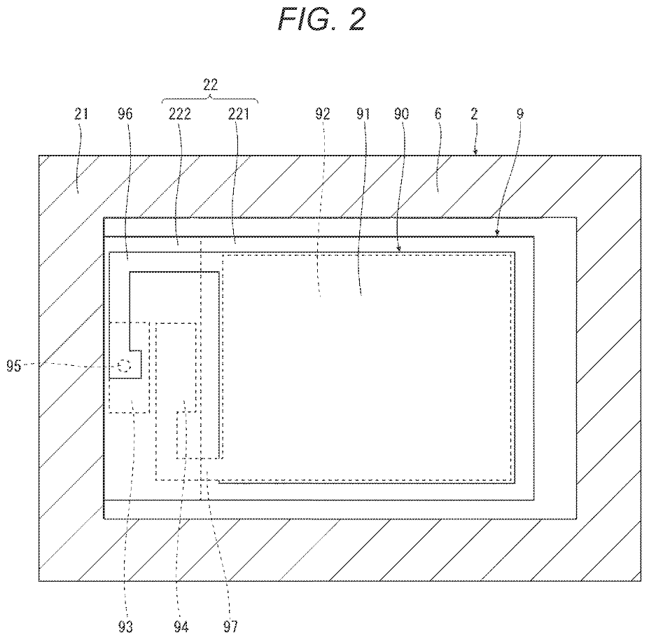

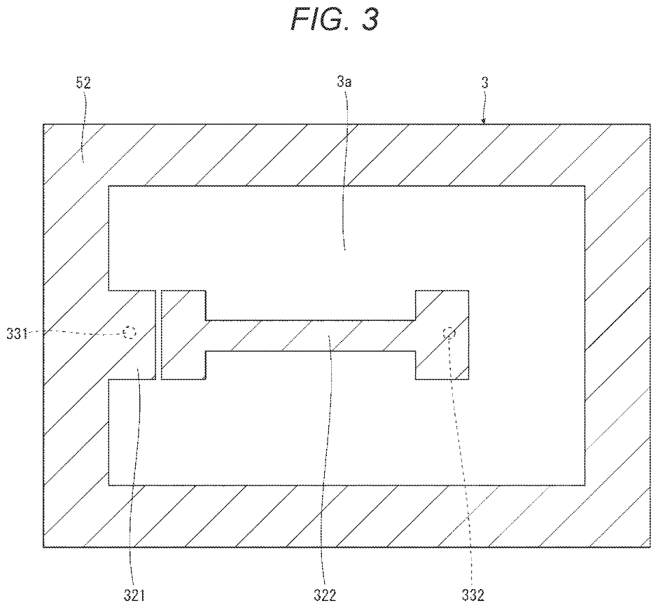

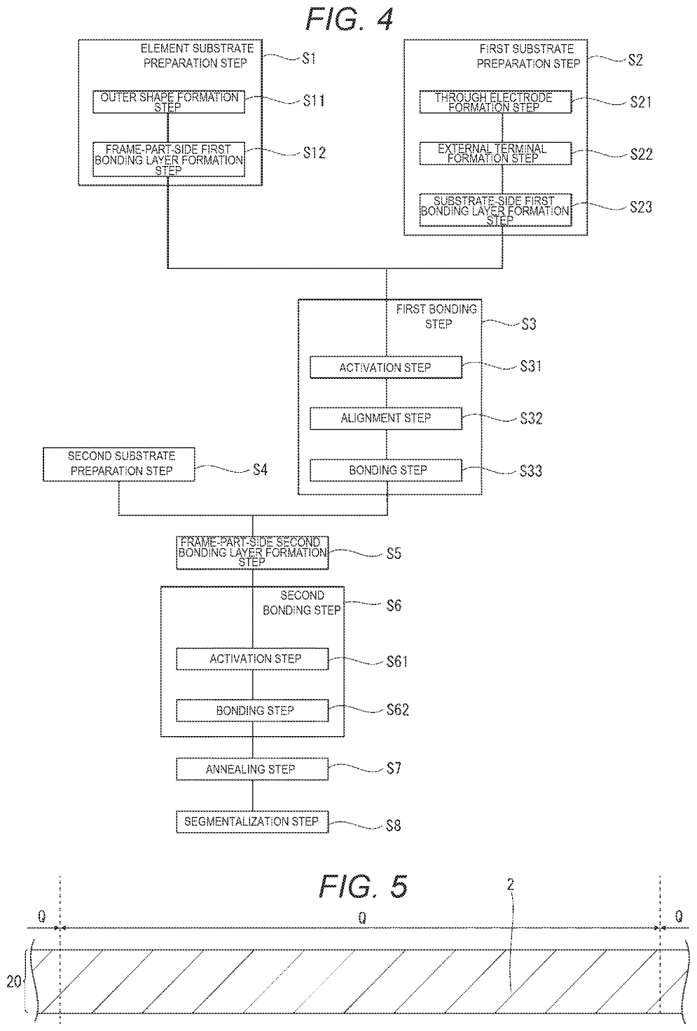

Some preferred embodiments of a resonator device and a method of manufacturing a resonator device will hereinafter be described based on the accompanying drawings. It should be noted that the upper side in each of FIG. 1, and FIG. 5 through FIG. 20 is also referred to as an “upper side,” and the lower side is also referred to as a “lower side” for the sake of convenience of explanation. In that case, in FIG. 2 and FIG. 3, a front side of the sheet corresponds to the “upper side,” and a back side corresponds to the “lower side.”

### First Embodiment

FIG. 1 is a cross-sectional view of a resonator device according to a first embodiment. FIG. 2 is a plan view showing an element substrate provided to the resonator device. FIG. 3 is a plan view of a first substrate provided to the resonator device. FIG. 4 is a flowchart showing a manufacturing process of the resonator device. FIG. 5 through FIG. 18 are each a cross-sectional view showing a method of manufacturing the resonator device.

The resonator device 1 shown in FIG. 1 is a quartz crystal resonator. The resonator device 1 has an element substrate 2 provided with a resonator element 9, a first substrate 3 arranged at a lower side of the element substrate 2, a second substrate 4 arranged at an upper side of the element substrate 2, a first bonding layer 5 arranged between the element substrate 2 and the first substrate 3 to bond these substrates to each other, and a second bonding layer 6 which is arranged between the element substrate 2 and the second substrate 4 to bond these substrates to each other. The resonator device 1 is provided with a configuration in which the element substrate 2 is vertically sandwiched with the first and second substrates 3, 4 to form an airtight housing part S for housing the resonator element 9 inside. It should be noted that the housing part S is in a reduced-pressure state, and preferably, in a state more approximate to a vacuum state. Therefore, the viscosity resistance decreases, and the oscillation characteristic of the resonator element 9 is improved.

### Element Substrate 2

The element substrate 2 is an AT-cut quartz crystal substrate, and has a thickness of, for example, about 40 μm. The element substrate 2 has a frame part 21 shaped like a frame, and a vibrating substrate 22 arranged inside the frame part 21. The frame part 21 has a lower surface 21b as a first surface and an upper surface 21a as a second surface which are in a front-back relationship with each other. The vibrating substrate 22 has a vibrating part 221 and a coupling part 222 which couples the vibrating part 221 and the frame part 21 to each other. The vibrating part 221 is thinner than the frame part 21, an upper surface of the vibrating part 221 is located below the upper surface 21a, and a lower surface of the vibrating part 221 is located at an upper side of the lower surface 21b. The coupling part 222 is thinner than the frame part 21, an upper surface of the coupling part 222 is coplanar with the upper surface of the vibrating part 221, and a lower surface of the coupling part 222 is coplanar with the lower surface 21b.

On the vibrating substrate 22, there are arranged electrodes 90, and the resonator element 9 is constituted by the vibrating substrate 22 and the electrodes 90. As shown in FIG. 2, the electrodes 90 have an excitation electrode 91 arranged on the upper surface of the vibrating part 221, an excitation electrode 92 arranged on the lower surface of the vibrating part 221 so as to be opposed to the excitation electrode 91, a pair of terminals 93, 94 arranged on the lower surface of the coupling part 222, a through electrode 95 penetrating the coupling part 222, and coupled to the terminal 93, an interconnection 96 arranged on the upper surface of the vibrating substrate 22, and coupling the through electrode 95 and the excitation electrode 91 to each other, and an interconnection 97 arranged on the lower surface of the vibrating substrate 22, and coupling the terminal 94 and the excitation electrode 92 to each other.

It should be noted that the configuration of the resonator element 9 is not limited to the configuration described above. For example, the resonator element 9 can be provided with a mesa structure in which a vibration area sandwiched between the excitation electrodes 91, 92 protrudes from the periphery of the vibration area, or can also be provided with an inverted-mesa structure in which the vibration area is recessed from the periphery of the vibration area in an opposite manner. Further, a bevel treatment for grinding the periphery of the vibrating substrate 22, or a convex treatment for changing the upper surface and the lower surface to a convex surface can be provided.

Further, the element substrate 2 is not limited to one formed of the AT-cut quartz crystal substrate, and can also be formed of a quartz crystal substrate other than the AT-cut quartz crystal substrate such as an X-cut quartz crystal substrate, a Y-cut quartz crystal substrate, a Z-cut quartz crystal substrate, a BT-cut quartz crystal substrate, an SC-cut quartz crystal substrate, or an ST-cut quartz crystal substrate. Further, the constituent material of the element substrate 2 is not limited to the quartz crystal, but it is possible for the element substrate 2 to be formed of a piezoelectric single-crystal body made of, for example, lithium niobate, lithium tantalate, lithium tetraborate, langasite crystal, potassium niobate, or gallium phosphate, or to be formed of a piezoelectric single-crystal body made of other materials than these.

Further, as shown in FIG. 1, on the lower surface 21b of the frame part 21, there is arranged a frame-part-side first bonding layer 51 formed like a frame along the lower surface 21b. The frame-part-side first bonding layer 51 is formed of a stacked body of a Ti layer (a titanium layer) as a foundation layer arranged on the lower surface 21b, and an Au layer (a gold layer) as a surface layer arranged on the Ti layer. The thickness of the Ti layer is not particularly limited, but is in a range of, for example, about no smaller than 0.1 nm and about no larger than 10 nm, and is about 5 nm in the present embodiment. Further, the thickness of the Au layer is not particularly limited, but is in a range of, for example, about no smaller than 50 nm and about no larger than 200 nm, and is about 100 nm in the present embodiment.

Further, on the upper surface 21a of the frame part 21, there is arranged a frame-part-side second bonding layer 61 formed like a frame along the upper surface 21a. The frame-part-side second bonding layer 61 is formed of a Ti layer arranged on the upper surface 21a. The thickness of the Ti layer is not particularly limited, but is in a range of, for example, about no smaller than 0.1 nm and about no larger than 5 nm, and is about 1 nm in the present embodiment. It should be noted that the configuration of the frame-part-side second bonding layer 61 is not particularly limited, and it is possible to make an Si layer (a silicon layer), a Ge layer (a germanium layer), or the like intervene between, for example, the upper surface 21a and the Ti layer. Thus, it is possible to enhance an insulating property of the second bonding layer 6, and thus, it is possible to prevent unintended short circuit and so on.

### First Substrate 3

The first substrate 3 is a quartz crystal substrate, and has a thickness of, for example, about 40 μm. A cutting angle of the first substrate 3 is not particularly limited, but the AT-cut is adopted in the present embodiment in accordance with the element substrate 2. Further, the first substrate 3 is arranged so as to coincide in directions of the crystal axes with the element substrate 2. Thus, it is possible to uniform the element substrate 2 and the first substrate 3 in linear expansion coefficient, and therefore, a thermal stress becomes difficult to be applied to the resonator element 9. Therefore, there is obtained the resonator device 1 having excellent vibration characteristics. It should be noted that the first substrate 3 is not particularly limited, and can be, for example, a glass substrate.

As shown in FIG. 1, the first substrate 3 has an upper surface 3a as a third surface and a lower surface 3b, wherein the upper surface 3a and the lower surface 3b have a front-back relationship with each other. Further, on the lower surface 3b, there are arranged external terminals 311, 312. Further, on the upper surface 3a, there is arranged a substrate-side first bonding layer 52 shaped like a frame along an outer edge of the upper surface 3a. The substrate-side first bonding layer 52 is bonded to the frame-part-side first bonding layer 51 to thereby form a first bonding layer 5. Further, inside the substrate-side first bonding layer 52, there are arranged wiring layers 321, 322. The wiring layer 321 is bonded to the terminal 93, and is at the same time electrically coupled to the external terminal 311 via a through electrode 331 penetrating the first substrate 3. Thus, the wiring layers 321, 322 and the resonator element 9 are electrically coupled to each other. Further, the wiring layer 322 is bonded to the terminal 94, and is at the same time electrically coupled to the external terminal 312 via a through electrode 332 penetrating the first substrate 3. It should be noted that the wiring layer 321 is integrally formed with the substrate-side first bonding layer 52 in the present embodiment as shown in FIG. 3, but this is not a limitation.

The bonding layer 52 and the wiring layers 321, 322 are the same in configuration as each other. Thus, it is possible to form the bonding layer 52 and the wiring layers 321, 322 in a lump in the same step as in the manufacturing method described later, and thus, it is possible to achieve simplification of the manufacturing process and reduction in manufacturing cost of the resonator device 1. The bonding layer 52 and the wiring layers 321, 322 are each constituted by a stacked body of a Ti layer as a foundation layer arranged on the upper surface 3a, and an Au layer as a surface layer arranged on the Ti layer. The thickness of the Ti layer is not particularly limited, but is in a range of, for example, no smaller than 0.1 nm and no larger than 10 nm, and is about 5 nm in the present embodiment. Further, the thickness of the Au layer is not particularly limited, but is in a range of, for example, about no smaller than 50 nm and about no larger than 200 nm, and is about 100 nm in the present embodiment.

### Second Substrate 4

The second substrate 4 is a quartz crystal substrate, and has a thickness of, for example, about 40 μm. A cutting angle of the second substrate 4 is not particularly limited, but the AT-cut is adopted in the present embodiment in accordance with the element substrate 2. Further, the second substrate 4 is arranged so as to coincide in directions of the crystal axes with the element substrate 2. Thus, it is possible to uniform the element substrate 2 and the second substrate 4 in linear expansion coefficient, and therefore, a thermal stress becomes difficult to be applied to the resonator element 9. Therefore, there is obtained the resonator device 1 having excellent vibration characteristics. It should be noted that the second substrate 4 is not particularly limited, and can be, for example, a glass substrate.

As shown in FIG. 1, the second substrate 4 has an upper surface 4a and a lower surface 4b as a fourth surface, wherein the upper surface 4a and the lower surface 4b have a front-back relationship with each other. Further, on the lower surface 4b, there is arranged a substrate-side second bonding layer 62 throughout the entire area thereof. The substrate-side second bonding layer 62 is formed of a Ti layer. The thickness of the Ti layer is not particularly limited, but is in a range of, for example, about no smaller than 0.1 nm and about no larger than 5 nm, and is about 1 nm in the present embodiment. It should be noted that the configuration of the substrate-side second bonding layer 62 is not particularly limited, and it is possible to make an Si layer (a silicon layer), a Ge layer (a germanium layer), or the like intervene between, for example, the lower surface 4b and the Ti layer. Thus, it is possible to enhance an insulating property of the second bonding layer 6, and thus, it is possible to prevent unintended short circuit and so on.

An outer edge part (a portion overlapping the frame-part-side second bonding layer 61) of the substrate-side second bonding layer 62 is bonded to the bonding layer 61 arranged on the upper surface 21a of the frame part 21 to thereby form the second bonding layer 6. On the other hand, a central portion (a portion exposed to the housing part S) of the bonding layer 62 has a gas adsorptive property, and functions as a getter layer 7 for adsorbing a residual gas in the housing part S. In other words, the bonding layer 62 also functions as the getter layer 7. Thus, it is possible to integrally form these layers, and thus, it is possible to achieve the simplification of the manufacturing process and the reduction in manufacturing cost of the resonator device 1.

By the getter layer 7 adsorbing the residual gas in the housing part S, deterioration in vacuum in the housing part S is prevented, and it is possible to effectively prevent the deterioration in vibration characteristics due to a fluctuation in vibrational frequency and deterioration in Q-value. Therefore, it is possible to stabilize the vibration characteristics of the resonator device 1 on a long-term basis. In particular, by forming the getter layer 7 with the Ti layer, it is possible to exert a high gas adsorptive property, and therefore, the advantages described above become conspicuous.

### First Bonding Layer 5

The first bonding layer 5 is located between the element substrate 2 and the first substrate 3 to bond these substrates to each other. As described above, the first bonding layer 5 is formed of the frame-part-side first bonding layer 51 (hereinafter simply referred to as a “bonding layer 51”) and the substrate-side first bonding layer 52 (hereinafter simply referred to as a “bonding layer 52”) bonded to each other, wherein the frame-part-side first bonding layer 51 is arranged on the lower surface 21b of the frame part 21, and the substrate-side first bonding layer 52 is arranged on the upper surface 3a of the first substrate 3. These bonding layers 51, 52 are bonded to each other using room temperature surface activated bonding. Specifically, surfaces of the bonding layers 51, 52 are irradiated with an ion beam or plasma, the surfaces are made to adhere to each other in the state in which the surfaces of the bonding layers 51, 52 are activated to diffuse and then reorganize the metal in the bonding layers 51, 52 to thereby form the first bonding layer 5, and thus, the element substrate 2 and the first substrate 3 are bonded to each other at room temperature. According to such a bonding method, it is possible to firmly bond the element substrate 2 and the first substrate 3 to each other. Further, since bonding can be achieved at room temperature, a residual stress is difficult to occur. It should be noted that the bonding method of the element substrate 2 and the first substrate 3 is not particularly limited.

In order to firmly bond the bonding layers 51, 52 to each other using the room temperature surface activated bonding described above, it is necessary for the surfaces of the bonding layers 51, 52 to be made smooth and to adhere to each other. Therefore, the surface roughness Ra of the lower surface 21b and the upper surface 3a is preferably made no higher than 5 nm, and is more preferably made no higher than 3 nm. Thus, the surfaces of the bonding layers 51, 52 to be formed thereon become sufficiently smooth surfaces, and it is possible to more firmly bond the bonding layers 51, 52.

### Second Bonding Layer 6

The second bonding layer 6 is located between the element substrate 2 and the second substrate 4 to bond these substrates to each other. As described above, the second bonding layer 6 is formed of the bonding layer 61 (hereinafter simply referred to as a “bonding layer 61”) and the bonding layer 62 (hereinafter simply referred to as a “bonding layer 62”) bonded to each other, wherein the bonding layer 61 is arranged on the upper surface 21a of the frame part 21, and the bonding layer 62 is arranged on the lower surface 4b of the second substrate 4. The bonding layers 61, 62 are bonded to each other using atomic diffusion bonding. It should be noted that the bonding method of the element substrate 2 and the second substrate 4 is not particularly limited. Further, in order to more firmly bond the bonding layers 61, 62 to each other, the surface roughness Ra of the upper surface 21a and the lower surface 4b is preferably made no higher than 5 nm, and is more preferably made no higher than 3 nm.

The configuration of the resonator device 1 is hereinabove described. As described above, such a resonator device 1 has the element substrate 2 having the frame part 21 provided with the lower surface 21b as the first surface and the upper surface 21a as the second surface having the front-back relationship with each other, and the resonator element 9 which is coupled to the frame part 21 and is arranged inside the frame part 21, the first substrate 3 which is arranged at the lower surface 21b side, and has the upper surface 3a as the third surface faced to the lower surface 21b, the first bonding layer 5 which is arranged between the element substrate 2 and the first substrate 3, and bonds the lower surface 21b and the upper surface 3a to each other, the second substrate 4 which is arranged at the upper surface 21a side, and has the lower surface 4b as the fourth surface faced to the upper surface 21a, the second bonding layer 6 which is arranged between the element substrate 2 and the second substrate 4, and bonds the upper surface 21a and the lower surface 4b to each other, the housing part S which is surrounded by the frame part 21, the first substrate 3, and the second substrate 4, and houses the resonator element 9, and the getter layer 7 which is arranged on the lower surface 4b, exposed to the housing part S, and has the gas adsorptive property. According to such a configuration, it is possible to adsorb the residual gas in the housing part S with the getter layer 7. Thus, the deterioration in vacuum in the housing part S is prevented, and it is possible to effectively prevent the deterioration in vibration characteristics due to a fluctuation in vibrational frequency, a decrease in Q-value, and so on. Therefore, it is possible to stabilize the vibration characteristics of the resonator device 1 on a long-term basis.

Further, as described above, the second bonding layer 6 has the substrate-side second bonding layer 62 arranged in the entire area on the lower surface 4b, wherein the portion exposed to the housing part S of the substrate-side second bonding layer 62 also functions as the getter layer 7. Thus, it is possible to integrally form these layers, and thus, it is possible to achieve the simplification of the manufacturing process and the reduction in manufacturing cost of the resonator device 1. Further, at the time of manufacture, since highly accurate alignment between the element substrate 2 and the second substrate 4 becomes unnecessary, it is possible to achieve the simplification of the manufacturing process and the reduction in manufacturing cost of the resonator device 1.

Further, as described above, the substrate-side second bonding layer 62 has the Ti layer. Thus, it is possible for the getter layer 7 to exert the excellent gas adsorptive property.

Further, as described above, the resonator device 1 has the wiring layers 321, 322 which are arranged on the upper surface 3a, and are electrically coupled to the resonator element 9, the first bonding layer 5 has the substrate-side first bonding layer 52 arranged on the upper surface 3a, and the substrate-side first bonding layer 52 and the wiring layers 321, 322 are the same in configuration as each other. Thus, it is possible to form these layers in a lump, and thus, it is possible to achieve the simplification of the manufacturing process and the reduction in manufacturing cost of the resonator device 1.

Further, as described above, the lower surface 21b, the upper surface 21a, the upper surface 3a, and the lower surface 4b are each no higher in surface roughness Ra than 5 nm. Thus, the surfaces of the bonding layers 51, 52, 61, and 62 to be formed on these surfaces become sufficiently smooth surfaces, and it is possible to more firmly bond the bonding layers 51, 52 to each other and bond the bonding layers 61, 62 to each other.

Then, a method of manufacturing the resonator device 1 will be described. As shown in FIG. 4, the method of manufacturing the resonator device 1 includes an element substrate preparation step S1 of preparing the element substrate 2 provided with the frame-part-side first bonding layer 51, a first substrate preparation step S2 of preparing the first substrate 3 provided with the substrate-side first bonding layer 52, a first bonding step S3 of bonding the element substrate 2 and the first substrate 3 to each other, a second substrate preparation step S4 of preparing the second substrate 4 provided with the substrate-side second bonding layer 62, a frame-part-side second bonding layer formation step S5 of providing the frame-part-side second bonding layer 61 to the element substrate 2, a second bonding step S6 of bonding the element substrate 2 and the second substrate 4 to each other, an annealing step S7 of performing an annealing processing, and a segmentalization step S8 of performing segmentalization.

### Element Substrate Preparation Step S1

As shown in FIG. 4, the element substrate preparation step S1 includes an outer shape formation step S11 of forming an outer shape of the element substrate 2, and a frame-part-side first bonding layer formation step S12 of providing the frame-part-side first bonding layer 51 to the element substrate 2.

### Outer Shape Formation Step S11

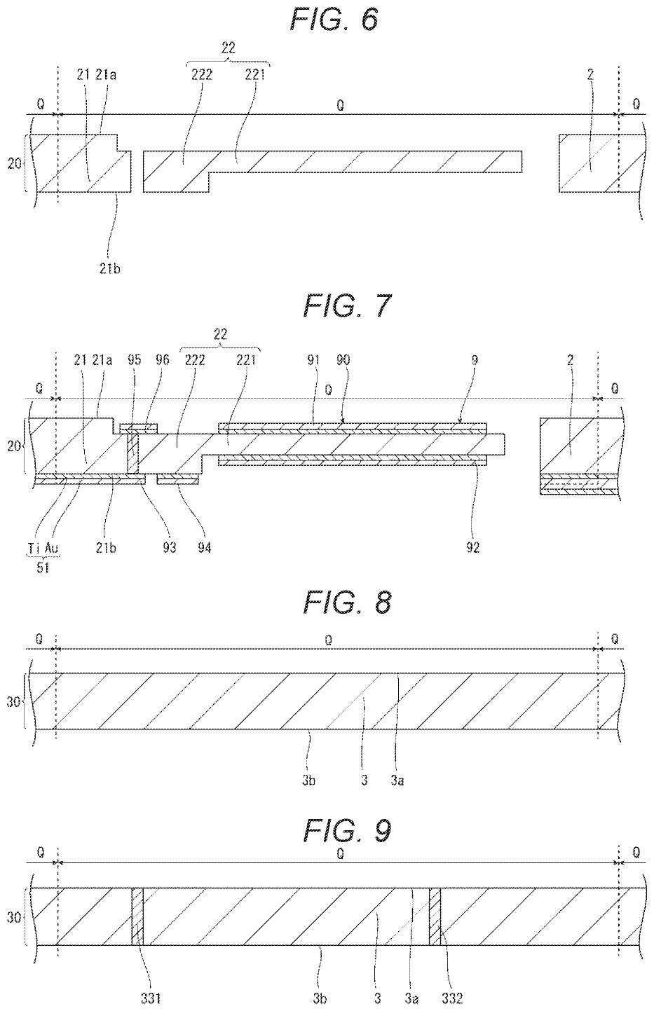

First, as shown in FIG. 5, an element wafer 20 to be a base material of the element substrate 2 is prepared. The element wafer 20 includes a plurality of segmentalization areas Q, namely a plurality of portions which is segmentalized into the element substrates 2. Then, as shown in FIG. 6, the element wafer 20 is patterned by etching to provide each of the element substrates 2 with the frame part 21 and the vibrating substrate 22 coupled to the frame part 21. It should be noted that the etching method is not particularly limited, and wet-etching, dry-etching, and so on can be used.

### Frame-Part-Side First Bonding Layer Formation Step S12

Then, after forming the through electrode 95, the Ti layer and the Au layer are sequentially deposited on the surface of the element substrate 2. The deposition method of the Ti layer and the Au layer is not particularly limited, and there can be used sputtering, CVD, vapor deposition, and so on. Then, as shown in FIG. 7, by patterning the Ti/Au stacked body using a photolithography technique and an etching technique, the frame-part-side first bonding layer 51 and the electrodes 90 are formed. Due to the process described above, there is obtained the element substrate 2 provided with the frame-part-side first bonding layer 51. It should be noted that in the element substrate preparation step S1, the frame-part-side second bonding layer 61 is not formed on the upper surface 21a of the frame part 21.

### First Substrate Preparation Step S2

As shown in FIG. 4, the first substrate preparation step S2 includes a through electrode formation step S21 of forming the through electrodes 331, 332, an external terminal formation step S22 of forming the external terminals 311, 312, and a substrate-side first bonding layer formation step S23 of forming the substrate-side first bonding layer 52 and the wiring layers 321, 322.

### Through Electrode Formation Step S21

First, as shown in FIG. 8, a first wafer 30 to be a base material of the first substrate 3 is prepared. The first wafer 30 has the upper surface 3a and the lower surface 3b in the front-back relationship with each other, and includes a plurality of segmentalization areas Q, namely a plurality of portions which is segmentalized into the first substrates 3. Then, as shown in FIG. 9, by providing the through holes to each of the first substrates 3, and then filling the through holes with the metal material, there are formed the through electrodes 331, 332.

### External Terminal Formation Step S22

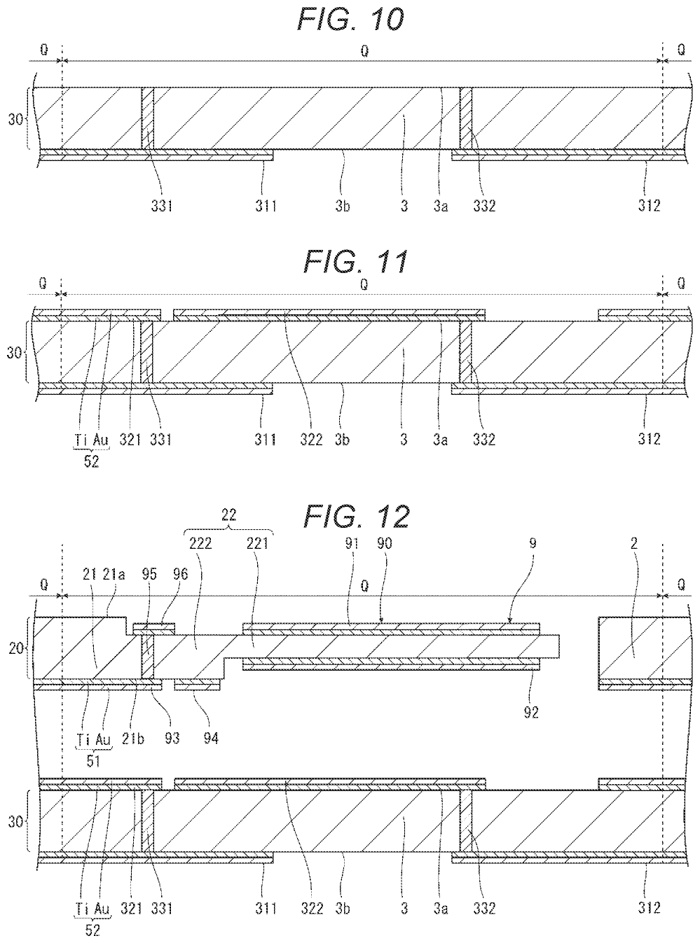

Then, a TiW alloy layer (a titanium-tungsten alloy layer) and the Au layer are sequentially deposited on the lower surface 3b of the first wafer 30. The method of depositing the TiW layer and the Au layer is not particularly limited, and there can be used sputtering, CVD, vapor deposition, and so on. Then, as shown in FIG. 10, by patterning the TiW/Au stacked body using a photolithography technique and an etching technique, the external terminals 311, 312 are formed on the lower surface 3b of each of the first substrates 3.

### Substrate-Side First Bonding Layer Formation Step S23

Then, the Ti layer and the Au layer are sequentially deposited on the upper surface 3a of the first wafer 30. The deposition method of the Ti layer and the Au layer is not particularly limited, and there can be used sputtering, CVD, vapor deposition, and so on. Then, as shown in FIG. 11, by patterning the Ti/Au stacked body using a photolithography technique and an etching technique, the substrate-side first bonding layer 52 and the wiring layers 321, 322 are formed in a lump on the upper surface 3a of each of the first substrates 3. By forming the substrate-side first bonding layer 52 and the wiring layers 321, 322 in a lump as described above, it is possible to achieve the simplification of the manufacturing process and the reduction in manufacturing cost of the resonator device 1. Due to the process described above, there is obtained the first substrate 3 provided with the substrate-side first bonding layer 52.

### First Bonding Step S3

As shown in FIG. 4, the first bonding step S3 includes an activation step S31 of activating the frame-part-side first bonding layer 51 and the substrate-side first bonding layer 52, an alignment step S32 of performing alignment between the element wafer 20 and the first wafer 30, and a bonding step S33 of bonding the element wafer 20 and the first wafer 30 to each other.

### Activation Step S31

First, the surfaces of the frame-part-side first bonding layer 51, the terminals 93, 94, the substrate-side first bonding layer 52, and the wiring layers 321, 322 are irradiated with an ion beam or plasma to thereby activate these surfaces.

### Alignment Step S32

Then, as shown in FIG. 12, alignment between the element wafer 20 and the first wafer 30 is performed using a camera and so on.

### Bonding Step S33

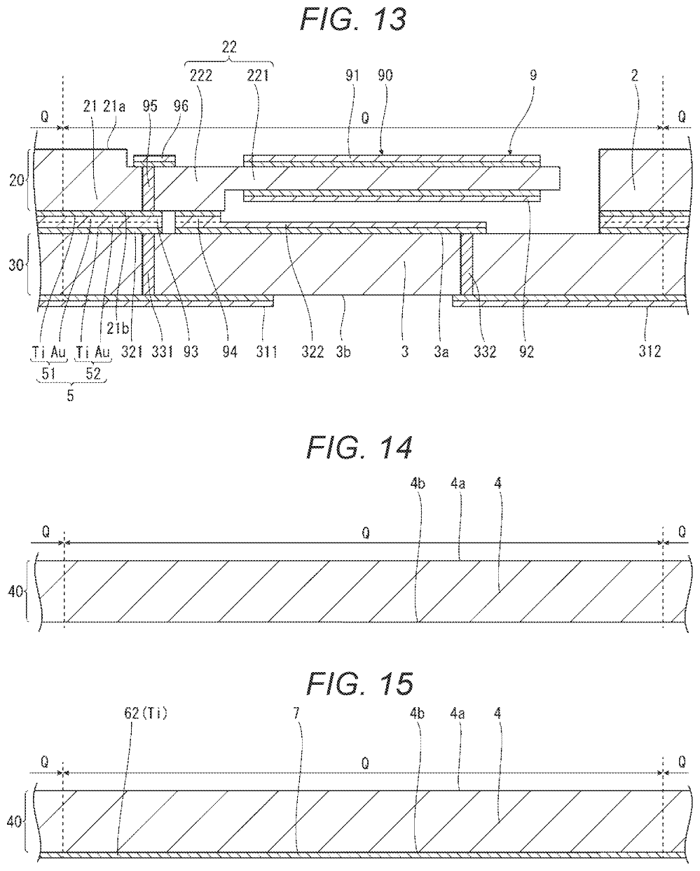

Then, as shown in FIG. 13, in the atmosphere at room temperature, the surfaces of the frame-part-side first bonding layer 51 and the substrate-side first bonding layer 52 are made to adhere to each other, and at the same time, the surfaces of the terminals 93, 94 and the wiring layers 321, 322 are made to adhere to each other, and then the metal in the frame-part-side first bonding layer 51 and the substrate-side first bonding layer 52 is diffused and then reorganized to thereby form the first bonding layer 5, and then the element wafer 20 and the first wafer 30 are bonded to each other via the first bonding layer 5. Further, by diffusing and then reorganizing the metal in the terminals 93, 94 and the wiring layers 321, 322, the terminals 93, 94 and the wiring layers 321, 322 are bonded to each other. According to such a bonding method, it is possible to firmly bond the element wafer 20 and the first wafer 30 to each other. It should be noted that when performing bonding, the element wafer 20 and the first wafer 30 can be pressurized, but are not required to be pressurized.

Here, the surface roughness Ra of the lower surface 21b and the upper surface 3a is not particularly limited, but is preferably no higher than 5 nm, and is more preferably no higher than 3 nm. Thus, it is possible to suppress the surface roughness of the frame-part-side first bonding layer 51 and the substrate-side first bonding layer 52 to be deposited on these surfaces to a sufficiently low level, and it is possible to more firmly bond the element wafer 20 and the first wafer 30 to each other.

It should be noted that the steps S31, S32, and S33 included in the first bonding step S3 are performed in the atmosphere. By performing the steps in the atmosphere, it is possible to accurately align the element wafer 20 and the first wafer 30 with each other in particular in the alignment step S32. Since it is necessary to achieve the electrical coupling between the resonator element 9 and the wiring layers 321, 322 by the bonding between the element wafer 20 and the first wafer 30, by performing the alignment step S32 with accuracy, it is possible to effectively prevent the conduction failure. It should be noted that in order to prevent oxidation of the frame-part-side first bonding layer 51 and the substrate-side first bonding layer 52 caused by the contact with the air, the Au layer is used as the surface layers of the frame-part-side first bonding layer 51 and the substrate-side first bonding layer 52. Thus, it is possible to firmly bond the element wafer 20 and the first wafer 30 to each other in the bonding step S33.

### Second Substrate Preparation Step S4

Then, as shown in FIG. 14, a second wafer 40 to be a base material of the second substrate 4 is prepared. The second wafer 40 has the upper surface 4a and the lower surface 4b in the front-back relationship with each other, and includes a plurality of segmentalization areas Q, namely a plurality of portions which is segmentalized into the second substrates 4. Then, as shown in FIG. 15, the Ti layer is deposited in the entire area on the lower surface 4b of the second wafer 40 in vacuum, to form the substrate-side second bonding layer 62. It should be noted that the deposition method of the Ti layer is not particularly limited, and there can be used sputtering, CVD, vapor deposition, and so on. Due to the process described above, there is obtained the second substrate 4 provided with the substrate-side second bonding layer 62.

### Frame-Part-Side Second Bonding Layer Formation Step S5

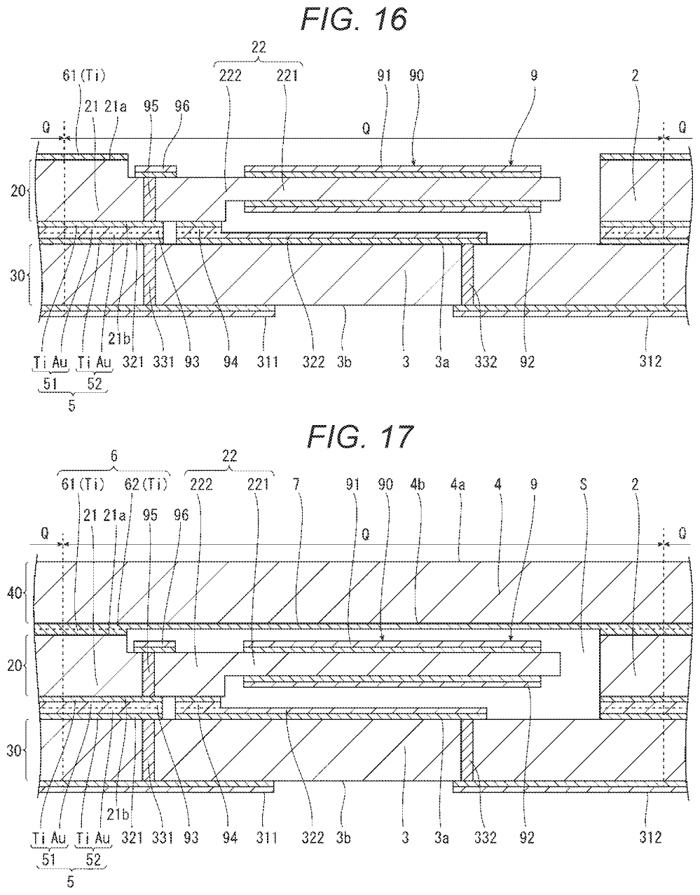

Then, as shown in FIG. 16, the Ti layer is deposited on the upper surface 21a of each of the frame parts 21 of the element wafer 20 in vacuum, to form the frame-part-side second bonding layer 61. It should be noted that the deposition method of the Ti layer is not particularly limited, and there can be used sputtering, CVD, vapor deposition, and so on. Due to the process described above, there is obtained the element substrate 2 provided with the frame-part-side second bonding layer 61.

### Second Bonding Step S6

As shown in FIG. 4, the second bonding step S6 includes an activation step S61 of activating the frame-part-side second bonding layer 61 and the substrate-side second bonding layer 62, and a bonding step S62 of bonding the element wafer 20 and the second wafer 40 to each other.

### Activation Step S61

First, in vacuum, the surfaces of the frame-part-side second bonding layer 61 and the substrate-side second bonding layer 62 are irradiated with an ion beam or plasma to thereby activate the surfaces of the frame-part-side second bonding layer 61 and the substrate-side second bonding layer 62.

### Bonding Step S62

Then, as shown in FIG. 17, in vacuum at room temperature, the surfaces of the frame-part-side second bonding layer 61 and the substrate-side second bonding layer 62 are made to adhere to each other in the state in which these surfaces are activated, and then the metal in the frame-part-side second bonding layer 61 and the substrate-side second bonding layer 62 is diffused and then reorganized to thereby form the second bonding layer 6, and then the element wafer 20 and the second wafer 40 are bonded to each other via the second bonding layer 6. Thus, the housing part S as a vacuum space for housing the resonator element 9 is formed. According to such a bonding method, it is possible to firmly bond the element wafer 20 and the second wafer 40 to each other. It should be noted that when performing bonding, the element wafer 20 and the second wafer 40 can be pressurized, but are not required to be pressurized.

The surface roughness Ra of the lower surface 4b and the upper surface 21a is not particularly limited, but is preferably no higher than 5 nm, and is more preferably no higher than 3 nm. Thus, it is possible to suppress the surface roughness of the frame-part-side second bonding layer 61 and the substrate-side second bonding layer 62 to be deposited on these surfaces to a sufficiently low level, and it is possible to more firmly bond the element wafer 20 and the second wafer 40 to each other.

Here, the second substrate preparation step S4 through the second bonding step S6 are performed continuously in vacuum without being exposed to the air during the steps. Thus, since the Ti layers constituting the frame-part-side second bonding layer 61 and the substrate-side second bonding layer 62 are not exposed to the air, it is possible to effectively prevent the oxidation of the Ti layers. Therefore, it is possible to exert the firm bonding between the element wafer 20 and the second wafer 40, and the high gas adsorptive property of the getter layer 7. Further, since it becomes unnecessary to cover the surfaces of the Ti layers with the surface layers such as Au layers in order to prevent the oxidation of the Ti layers, it is possible to achieve the simplification of the manufacturing process and the reduction in manufacturing cost of the resonator device 1.

It should be noted that since the element wafer 20 and the second wafer 40 are not required to electrically be coupled to each other, and the substrate-side second bonding layer 62 is formed in the entire area on the lower surface 4b of the second wafer 40, the highly accurate positioning between the element wafer 20 and the second wafer 40 becomes unnecessary. Therefore, even when some restrictions occur in the positioning between the element wafer 20 and the second wafer 40 in a chamber for forming a vacuum atmosphere, the restrictions do not present a severe problem in the manufacturing process, and a disadvantage such as deterioration in yield does not substantially occur.

### Annealing Step S7

Then, the stacked body of the element wafer 20, the first wafer 30, and the second wafer 40 is heated at the temperature in a range no lower than 200° C. and no higher than 300° C. to perform an annealing treatment. Thus, the getter layer 7 is activated, the residual gas in each of the housing parts S is adsorbed by the getter layer 7, and thus, a degree of vacuum of the housing part S increases.

### Segmentalization Step S8

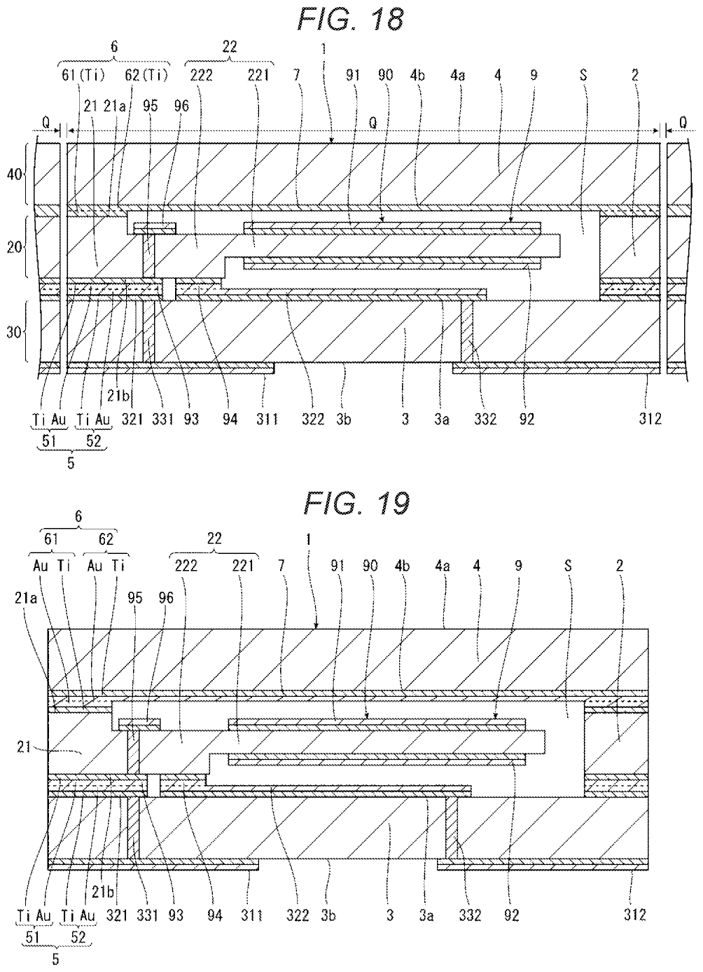

Then, as shown in FIG. 18, the stacked body of the element wafer 20, the first wafer 30, and the second wafer 40 is segmentalized into the segmentalization areas Q using a dicing blade or the like. Thus, a plurality of the resonator devices 1 is formed in a lump.

The resonator element 1 can be manufactured through the steps described above. According to such a method of manufacturing the resonator device 1, it is possible to easily manufacture the resonator device 1 in which the deterioration in vibration characteristics can effectively be suppressed by the getter layer 7 adsorbing the residual gas in the housing part S.

The method of manufacturing the resonator device 1 is hereinabove described. As described above, the method of manufacturing the resonator device 1 includes the element substrate preparation step S1 of preparing the element substrate 2 having the frame part 21 provided with the lower surface 21b as the first surface and the upper surface 21a as the second surface having the front-back relationship with each other, the resonator element 9 which is coupled to the frame part 21 and is arranged inside the frame part 21, and the frame-part-side first bonding layer 51 arranged on the lower surface 21b of the frame part 21, the first substrate preparation step S2 of preparing the first substrate 3 provided with the substrate-side first bonding layer 52 arranged on the upper surface 3a as the third surface, the first bonding step S3 of bonding the frame-part-side first bonding layer 51 and the substrate-side first bonding layer 52 to each other to form the first bonding layer 5, and then bonding the frame part 21 and the first substrate 3 to each other via the first bonding layer 5, the second substrate preparation step S4 of preparing the second substrate 4 having the lower surface 4b as the fourth surface on which the getter layer 7 having the gas adsorptive property, and the substrate-side second bonding layer 62 are arranged, the frame-part-side second bonding layer formation step S5 of forming the frame-part-side second bonding layer 61 on the upper surface 21a of the frame part 21, and the second bonding step S6 of bonding the frame-part-side second bonding layer 61 and the substrate-side second bonding layer 62 to each other to form the second bonding layer 6, and then bonding the frame part 21 and the second substrate 4 to each other via the second bonding layer 6. According to such a manufacturing method, it is possible to easily manufacture the resonator device 1 in which the deterioration in vibration characteristics can effectively be suppressed by the getter layer 7 adsorbing the residual gas in the housing part S.

Further, as described above, the method of manufacturing the resonator device 1 includes the annealing step S7 which is performed after the second bonding step S6, and in which the annealing treatment is performed on the stacked body of the element substrate 2, the first substrate 3, and the second substrate 4. Thus, the getter layer 7 is activated, the residual gas in each of the housing parts S is adsorbed by the getter layer 7, and thus, the degree of vacuum of the housing part S increases.

Further, as described above, in the method of manufacturing the resonator device 1, the substrate-side second bonding layer 62 also functions as the getter layer 7, and is arranged in the entire area on the lower surface 4b. Thus, the highly accurate positioning between the element substrate 2 and the second substrate 4 becomes unnecessary. Therefore, it is possible to achieve the simplification of the manufacturing process and the reduction in manufacturing cost of the resonator device 1.

Further, as described above, in the method of manufacturing the resonator device 1, by forming the wiring layers 321, 322 the same in configuration as the substrate-side first bonding layer 52 on the upper surface 3a in the first substrate preparation step S2, and bonding the frame part 21 and the first substrate 3 to each other via the first bonding layer 5 in the first bonding step S3, the resonator element 9 and the wiring layers 321, 322 are electrically coupled to each other. By making the wiring layers 321, 322 the same in configuration as the substrate-side first bonding layer 52, it is possible to form the substrate-side first bonding layer 52 and the wiring layers 321, 322 in a lump, and therefore, it is possible to achieve the simplification of the manufacturing process and the reduction in manufacturing cost of the resonator device 1.

Further, as described above, in the method of manufacturing the resonator device 1, the second substrate preparation step S4, the frame-part-side second bonding layer formation step S5, and the second bonding step S6 are continuously performed in a reduced pressure atmosphere, in particular, in vacuum without being exposed to the air during the steps. Thus, it is possible to effectively prevent the oxidation of the frame-part-side second bonding layer 61 and the substrate-side second bonding layer 62. Therefore, it is possible to exert the firm bonding between the element substrate 2 and the second substrate 4, and the high gas adsorptive property of the getter layer 7. Further, since it becomes unnecessary to deposit the surface layer for preventing the oxidation, it is possible to achieve the simplification of the manufacturing process and the reduction in manufacturing cost of the resonator device 1.

### Second Embodiment

FIG. 19 is a cross-sectional view of a resonator device according to a second embodiment.

The resonator device 1 according to the present embodiment is substantially the same as the resonator device according to the first embodiment described above except the point that the configuration of the second bonding layer 6 is different. Therefore, in the following description, the present embodiment will be described with a focus on the difference from the first embodiment described above, and the description of substantially the same issues will be omitted. Further, in the drawings in the present embodiment, the constituents substantially the same as in the embodiment described above are denoted by the same reference symbols.

As shown in FIG. 19, in the present embodiment, the frame-part-side second bonding layer 61 and the substrate-side second bonding layer 62 are each further provided with an Au layer arranged on the Ti layer. Thus, it is possible to prevent the oxidation of the Ti layer caused by the exposure to the atmosphere. Therefore, the necessity in the first embodiment described above of, for example, continuously performing the second substrate preparation step S4 through the second bonding step S6 in vacuum without being exposed to the atmosphere during the steps disappears, and thus, the restrictions in the manufacturing process are reduced. Therefore, it becomes easy to manufacture the resonator device 1. Further, the bonding layers 51, 52, 61, and 62 become the same in configuration as each other, and the bonding method of the bonding layers 51, 52 and the bonding method of the bonding layers 61, 62 also become the same as each other. Therefore, it is possible to achieve commonalization of the deposition apparatus and bonding apparatus, and thus, it becomes easy to manufacture the resonator device 1.

Further, in the getter layer 7, by titanium atoms in the Ti layer being diffused in the Au layer, it is possible to exert the gas adsorptive property. In particular, by heating the second bonding layer 6 in the annealing step S7, it is possible to promote the diffusion of the titanium atoms to an Au film. The thickness of the Au layer of the substrate-side second bonding layer 62 is not particularly limited, but is in a range of, for example, no smaller than 5 nm and no larger than 100 nm, and is about 20 nm in the present embodiment. Thus, it is possible to sufficiently ensure the bonding characteristics with the frame-part-side second bonding layer 61, and further, it becomes easy for the titanium atoms to be diffused in the getter layer 7 up to the surface of the Au layer, and thus, it is possible to exert an excellent gas adsorptive property.

As described hereinabove, in the resonator device 1 according to the present embodiment, the substrate-side second bonding layer 62 has the Au layer arranged on the Ti layer. Thus, it is possible to prevent the oxidation of the Ti layer caused by the exposure to the atmosphere. Therefore, the necessity in the first embodiment described above of, for example, continuously performing the second substrate preparation step S4 through the second bonding step S6 in vacuum without being exposed to the atmosphere during the steps disappears, and thus, the restrictions in the manufacturing process are reduced. Therefore, it becomes easy to manufacture the resonator device 1.

Further, as described above, the thickness of the Au layer in the substrate-side second bonding layer 62 is no larger than 100 nm. Thus, it becomes easy for the titanium atoms to be diffused in the getter layer 7 up to the surface of the Au layer, and thus, it is possible to exerts the excellent gas adsorptive property.

According also to such a second embodiment as described above, there can be exerted substantially the same advantages as in the first embodiment described above.

### Third Embodiment

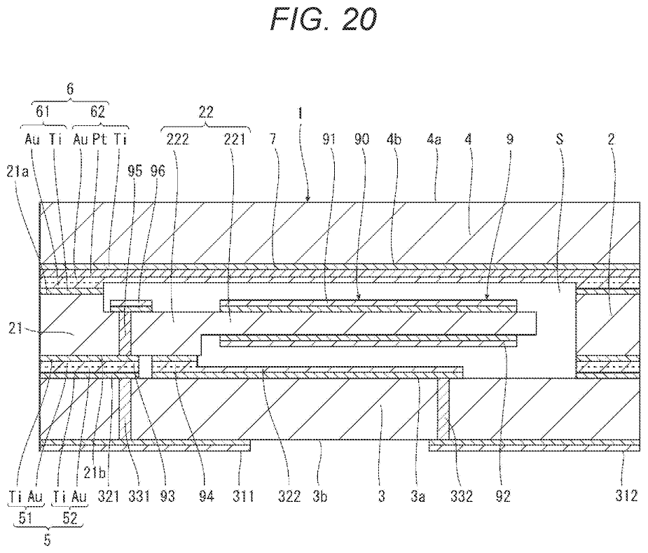

FIG. 20 is a cross-sectional view of a resonator device according to a third embodiment.

The resonator device 1 according to the present embodiment is substantially the same as the resonator device according to the second embodiment described above except the point that the configuration of the second bonding layer 6 is different. Therefore, in the following description, the present embodiment will be described with a focus on the difference from the second embodiment described above, and the description of substantially the same issues will be omitted. Further, in the drawings in the present embodiment, the constituents substantially the same as in the embodiment described above are denoted by the same reference symbols.

As shown in FIG. 20, in the present embodiment, the substrate-side second bonding layer 62 further has a Pt layer (a platinum layer) intervening between the Ti layer and the Au layer. Due to the Pt layer, it is possible to suppress the diffusion of the titanium atoms at room temperature to the Au layer. Thus, it is possible to prevent degradation in bonding characteristics of the substrate-side second bonding layer 62. It should be noted that by heating the second bonding layer 6 in the annealing step S7 after the second bonding step S6, the titanium atoms are diffused to the Au layer via the Pt layer, and there is created the state of being capable of exerting the function as the getter layer 7. Further, by controlling the annealing temperature, it is also possible to control the diffusion amount of the titanium atoms to the Au layer.

It should be noted that the thickness of the Pt layer is not particularly limited, but can be set in a range of, for example, about no smaller than 1 nm and about no larger than 10 nm, and is 5 nm in the present embodiment. According to such a thickness, it is possible to more surely exert a diffusion control function that no titanium atom is diffused to the Au layer at room temperature while the titanium atoms are diffused to the Au layer at high temperature. Further, the thickness of the Au layer is not particularly limited, but can be set in a range of, for example, about no smaller than 1 nm and about no larger than 10 nm, and is 3 nm in the present embodiment.

According also to such a third embodiment as described above, substantially the same advantages as in the first embodiment described above can be exerted.

Although the resonator device and the method of manufacturing the resonator device according to the present disclosure are hereinabove described based on the illustrated embodiments, the present disclosure is not limited to the embodiments, but the configuration of each of the components can be replaced with one having substantially the same function and an arbitrary configuration. Further, the present disclosure can also be added with any other constituents. Further, it is also possible to arbitrarily combine any of the embodiments with each other.

What is claimed is:

1. A resonator device comprising:
an element substrate including a frame part having a first surface and a second surface in a front-back relationship with each other, and a resonator element which is coupled to the frame part, and is arranged inside the frame part;
a first substrate which is arranged at the first surface side, and has a third surface faced to the first surface;
a first bonding layer which is arranged between the element substrate and the first substrate, and which is configured to bond the first surface and the third surface to each other;
a second substrate which is arranged at the second surface side, and has a fourth surface faced to the second surface;
a second bonding layer which is arranged between the element substrate and the second substrate, and which is configured to bond the second surface and the fourth surface to each other;
a housing part which is surrounded by the frame part, the first substrate, and the second substrate, and which is configured to house the resonator element; and
a getter layer which is arranged on the fourth surface, exposed to the housing part, and has a gas adsorptive property.

2. The resonator device according to claim 1, wherein
the second bonding layer has a substrate-side second bonding layer arranged in an entire area on the fourth surface, and
a portion of the substrate-side second bonding layer exposed to the housing part functions as the getter layer.

3. The resonator device according to claim 2, wherein
the substrate-side second bonding layer has a Ti layer.

4. The resonator device according to claim 3, wherein
the substrate-side second bonding layer has an Au layer arranged on the Ti layer.

5. The resonator device according to claim 4, wherein
a thickness of the Au layer is no larger than 100 nm.

6. The resonator device according to claim 1, further comprising:
a wiring layer which is arranged on the third surface, and which is electrically coupled to the resonator element, wherein
the first bonding layer has a substrate-side first bonding layer arranged on the third surface, and
the substrate-side first bonding layer and the wiring layer are same in configuration.

7. The resonator device according to claim 1, wherein
a surface roughness of the first surface, the second surface, the third surface, and the fourth surface is set no higher than 5 nm.

8. A method of manufacturing a resonator device comprising:
an element substrate preparation step of preparing an element substrate including a frame part having a first surface and a second surface in a front-back relationship, a resonator element which is coupled to the frame part, and is arranged inside the frame part, and a frame-part-side first bonding layer arranged on the first surface of the frame part;
a first substrate preparation step of preparing a first substrate provided with a substrate-side first bonding layer arranged on a third surface;
a first bonding step of bonding the frame-part-side first bonding layer and the substrate-side first bonding layer to each other to form a first bonding layer, and then bonding the frame part and the first substrate to each other via the first bonding layer;
a second substrate preparation step of preparing a second substrate having a fourth surface on which a getter layer having a gas adsorptive property, and a substrate-side second bonding layer are arranged;
a frame-part-side second bonding layer formation step of forming a frame-part-side second bonding layer on the second surface of the frame part; and
a second bonding step of bonding the frame-part-side second bonding layer and the substrate-side second bonding layer to each other to form a second bonding layer, and then bonding the frame part and the second substrate to each other via the second bonding layer.

9. The method of manufacturing the resonator device according to claim 8, further comprising:
an annealing step which is performed after the second bonding step, and in which an annealing treatment is performed on a stacked body of the element substrate, the first substrate, and the second substrate.

10. The method of manufacturing the resonator device according to claim 8, wherein
the substrate-side second bonding layer functions as the getter layer, and is arranged in an entire area on the fourth surface.

11. The method of manufacturing the resonator device according to claim 8, wherein
a wiring layer same in configuration as the substrate-side first bonding layer is formed on the third surface in the first substrate preparation step, and
the resonator element and the wiring layer are electrically coupled to each other by bonding the frame part and the first substrate to each other via the first bonding layer in the first bonding step.

12. The method of manufacturing the resonator device according to claim 8, wherein
the second substrate preparation step, the frame-part-side second bonding layer formation step, and the second bonding step are continuously performed in a reduced pressure atmosphere without being exposed to atmosphere during the steps.
